(19) United States
(12) Patent Application Publication
(10) Pub. No.: US 2009/0096522 A1
(43) Pub. Date: Apr. 16, 2009

(54) AMPLIFIER CIRCUIT

(76) Inventors: Etsuo Tsuchiya, Fuji-shi (JP); Toshinori Sueishi, Fuji-shi (JP); Reichiro Kobana, Fuji-shi (JP)

Correspondence Address: SNELL & WILMER LLP (OC), 600 ANTON BOULEVARD, SUITE 1400, COSTA MESA, CA, 92626, US

(21) Appl. No.: 12/279,828

(22) PCT Filed: Oct. 5, 2006
(86) PCT No.: PCT/JP2006/320357

§ 371 Date: Aug. 18, 2008

(30) Foreign Application Priority Data
Mar. 7, 2006 (JP) 2006-061897

(51) Int. Cl. H03F 1/32

(52) U.S. Cl. 330/149

(57) ABSTRACT

An amplifier circuit easily suppresses an intermodulation distortion signal incident to amplification. An input signal is class A amplified to be [symbol] times stronger on a path of a first amplifier 102, resulting in an input signal component F1 and F2 of power [symbol] F, and intermodulation distortion signal components (2F1-F2) and (2F2-F1) of power Fk1. The input signal is class AB amplified to be À times ( [symbol] >À) stronger on a path of a second amplifier 103, resulting in an input signal component F1 and F2 of power ÀF, and intermodulation distortion signal components (2F1-F2) and (2F2-F1) of power Fk2. A combiner 104 combines the input signal component F1 and F2 of power [symbol] F and the intermodulation distortion signal components (2F1-F2) and (2F2-F1) of power Fk1 with the input signal component F1 and F2 of power ÀAF and the intermodulation distortion signal components (2F1-F2) and (2F2-F1) of power Fk2.

### TECHNICAL FIELD

The present invention relates to an amplifier circuit for amplifying a signal.

### BACKGROUND ART

Conventionally, an amplifier circuit called a power amp is used to amplify a transmission signal to a transmission level in a wireless communication device.

In this kind of amplifier circuit, intermodulation distortion occurs as a result of amplifying an input signal in a characteristic region (in other words, a nonlinear region) in which the output signal is at a saturation level.

When such intermodulation distortion occurs in a modulation signal, distortion of the amplitude component and the phase component of the signal cause a problem of increased leaked power to adjacent channels due to expansion of the spectrum in frequency bands in the vicinity of a carrier frequency.

In view of this problem, one conventional method that has been proposed to suppress such intermodulation distortion is a method that uses a predistortion circuit.

The following publications disclose a predistortion circuit that generates a distortion signal by adding, to the input signal, a compensation signal obtained by giving predetermined phase and level fluctuation to the higher harmonic of the input signal.

1. HORIKAWA Koji, “Even-Order Distortion ni yoru Koshuturyoku Zofukuki Hizumi Teigen no Teian” (“Proposal for Reducing High Power Amplifier Distortion According to Even-Order Distortion”), Society Conference for the Institute of Electronics, Information and Communication Engineers B-230, 1996.

2. NAKAYAMA Masatoshi and TAKAGI Tadashi, “Denryoku Zofuki no Teihizumi Kokoritsuka no Shuho” (“Techniques for Low Distortion and High Efficiency. Power Amplifiers”), Mitsubishi Electric Corporation, 2004.

Referring to FIG. 12, the following briefly describes an amplifier circuit disclosed by the above publications.

As shown in FIG. 12, a circuit 800 is has a main signal path and a compensation signal generation path. The main signal path includes a divider 802, an amplitude modulator 806, a low-pass filter 807, and an amplifier 808. The compensation signal generation path includes a even number product generator 803, a high-pass filter (HPF) 804 and a phase shifter/variable attenuator 805.

The divider 802 divides an input signal from an input terminal 801, into the main signal path and the compensation signal generation path.

The even number product generator 803 generates an even number product of the input signal, from the signal divided into the compensation signal generation path.

The high-pass filter 804 rejects the carrier frequency band of the input signal, and extracts the even number harmonic of the input signal from the output signal of the even number product generator 803.

The phase shifter/variable attenuator 805 adjusts the phase and amplitude of the even number harmonic, and outputs the resultant signal.

The amplitude modulator 806, which is realized using a dual gate FET (field effect transistor) for instance, uses the output signal from the phase shifter/variable attenuator 805 to amplitude modulate the signal divided into the main signal path.

The low pass filter 807 rejects a third harmonic frequency band and higher of the carrier frequency band of the input signal, extracts a distortion signal that includes an object signal and only a second harmonic of the object signal from the amplitude-modulated signal, and outputs the extracted distortion signal from an output terminal 808.

The distortion signal is amplified by a compensated power amp (not illustrated). Adjusting the phase and amplitude in accordance with the nonlinear property of this compensated power amp reduces the distortion component that occurs in the output signal from the compensated power amp.

However, with such a conventional predistortion circuit, it is difficult to guarantee intermodulation distortion in a high power amplifier.

For instance, in transmission equipment in systems, such as digital broadcasting and mobile communications, in which digital multiplexing must be performed, high output amplifier circuits are used in order to generate a peak envelope power (Ppep) that is several tens of times greater from an average power (Pave) used on average.

However, in a circuit with a high output, the level of intermodulation distortion is high and varies greatly depending on environmental factors such as the temperate around the amplifier circuit. For this reason, it is difficult to appropriately determine the extent to which the phase and amplitude should be adjusted in the predistortion circuit.

### DISCLOSURE OF THE INVENTION

In view of this problem, the present invention has an object of providing an amplifier circuit that is capable of easily suppressing an intermodulation distortion signal that accompanies amplification.

In order to achieve the stated object, the present invention is an amplifier circuit including: a first amplifier and a second amplifier for amplifying an input signal that includes a plurality of frequency components; and a combiner for combining an output signal of the first amplifier with an output signal of the second amplifier, wherein a circuit structure of the amplifier circuit is such that distortion compensation is performed as a result of the combining, by using a signal in the output signal of the second amplifier to suppress a signal of a frequency component caused by intermodulation distortion in the output signal of the first amplifier, the signal in the output signal of the second amplifier having a reverse characteristic to the frequency component.

According to the stated structure, an intermodulation distortion signal generated when the input signal is amplified by the first amplifier can be suppressed using a second amplifier provided separately to the first amplifier.

Here, the amplifier circuit may further include: a divider for dividing the input signal into the first amplifier and the second amplifier, wherein the input signal includes a signal component of frequency f₁ and a signal component of frequency f₂, the divider divides the input signal to the first amplifier without changing a phase of the input signal, and divides the input signal to the second amplifier with the phase reversed, the first amplifier and the second amplifier are connected in parallel between the divider, and the combiner, the combiner combines the output signal of the first amplifier with the output signal of the second amplifier without changing a phase of each output signal, a control terminal of an amplification element of the first amplifier has applied thereto a bias voltage that causes the first amplifier to perform class A operation, and a control terminal of an amplification element of the second amplifier has applied thereto a predetermined bias voltage that causes the second amplifier to perform class AB operation and that is lower than the bias voltage applied to the control terminal of the amplification element of the first amplifier, such that at least (a) a signal component of frequency (2f₁-f₂) generated by intermodulation distortion in the output signal of the first amplifier and (b) a signal component of frequency (2f₁-f₂) in the output signal of the second amplifier cancel each other out as the result of the combining.

According to the stated structure, the intermodulation distortion signal generated due to the amplification by the first amplifier can be easily suppressed by adjusting the level of amplification of the second amplifier provided in parallel with the first amplifier. In particular, the level of amplification of the second amplifier for canceling out the intermodulation distortion can be easily adjusted by adjusting the gate voltage.

Here, the amplifier circuit may further include: a divider for dividing the input signal into the first amplifier and the second amplifier, wherein the input signal includes a signal component of frequency f₁ and a signal component of frequency f₂, the divider divides the input signal to the first amplifier without changing a phase of the input signal0, and divides the input signal to the second amplifier with the phase reversed, the first amplifier and the second amplifier are connected in parallel between the divider and the combiner, the divider and the second amplifier are connected via a resistor circuit that includes a resistor for dividing voltage of an output signal of the divider, and supplying a resultant signal to the second amplifier circuit, the combiner combines the output signal of the first amplifier with the output signal of the second amplifier without changing a phase of each output signal, the first amplifier and the second amplifier are set such that at least (a) a signal component of frequency (2f₁-f₂) caused by intermodulation distortion in the output signal of the first amplifier and (b) a signal component of frequency (2f₁-f₂) in the output signal of the second amplifier cancel each other out as the result of the combining.

According to the stated structure, the amplifier circuit can be manufactured to be compact in size and with low cost, because a device that has a lower level of amplification and lower rated power than the first amplifier can be used for the second amplifier.

Here, the amplifier circuit may further include: a divider for dividing the input signal into the first amplifier and the second amplifier, wherein the input signal includes a signal component of frequency f₁ and a signal component of frequency f₂, the first amplifier and the second amplifier are connected in parallel between the divider and the combiner, the divider and the second amplifier are connected via a distortion circuit that causes intermodulation distortion in an output signal of the divider, the distortion circuit includes a variable phase shifter, a variable attenuator, and a diode that adjusts a phase relationship between frequency components of the output signal of the divider, and the distortion circuit, the divider and the combiner are structured such that at least (a) a signal component of frequency (2f₁-f₂) caused by intermodulation distortion in the output signal of the first amplifier and (b) a signal component of frequency (2f₁-f₂) in the output signal of the second amplifier cancel each other out as a result of the combining.

According to the stated structure, finely adjusting the diode, the variable phase shifter, and the variable attenuator of the distortion circuit enables the level of amplification of the second amplifier to be finely tuned such that the intermodulation distortion is cancelled out.

Here, the amplifier circuit may further include: a setting circuit for successively measuring an output signal that is a result of amplification by the amplifier circuit, and, in accordance with a result of measuring, setting an amount of variation in the variable phase shifter and an amount of variation in the variable attenuator.

According to the stated structure, distortion compensation can be performed appropriately in response to aging.

Here, the second amplifier may have a lower rated voltage than the first amplifier.

According to the stated structure, the amplifier circuit can be manufactured to be compact in size and with low cost.

Here, each of the first amplifier and the second amplifier may be a GaN-HEMT, and may be composed of an internal matching integrated circuit.

According to the stated structure, appropriate characteristics in various fields of communication can be obtained because GaN-HEMTs that are superior in terms of linearity are used in a circuit that performs high frequency amplification.

### BRIEF DESCRIPTION OF THE DRAWINGS

FIG. 1 is a block diagram showing the structure of an amplifier circuit 100 of a first embodiment;

FIG. 2 is a graph showing properties of input voltage Vin versus output voltage Vout of a first amplifier 102;

FIGS. 3A and 3B are graphs showing a frequency versus amplitude relationship of input signal components and intermodulation distortion signal components;

FIG. 4 is a block diagram showing the structure of the amplifier circuit 100 used in a multistage structure;

FIG. 5 is a block diagram showing the structure of a digital broadcast repeater in which the amplifier circuit 100 is provided;

FIG. 6 is a block diagram showing the structure of a mobile communication base station in which the amplifier circuit 100 is provided;

FIG. 7 is a block diagram showing the structure of an amplifier circuit 200 of a second embodiment;

FIG. 8 is a block diagram showing the structure of the amplifier circuit 200 used in a multistage structure;

FIG. 9 is a block diagram showing the structure of an amplifier circuit 300 of a third embodiment;

FIG. 10 is a block diagram showing the structure of the amplifier circuit 300 used in a multistage structure;

FIG. 11 is a block diagram showing a compensation circuit 400 provided in the amplifier circuit 100; and

FIG. 12 is a block diagram showing the structure of a conventional predistortion circuit.

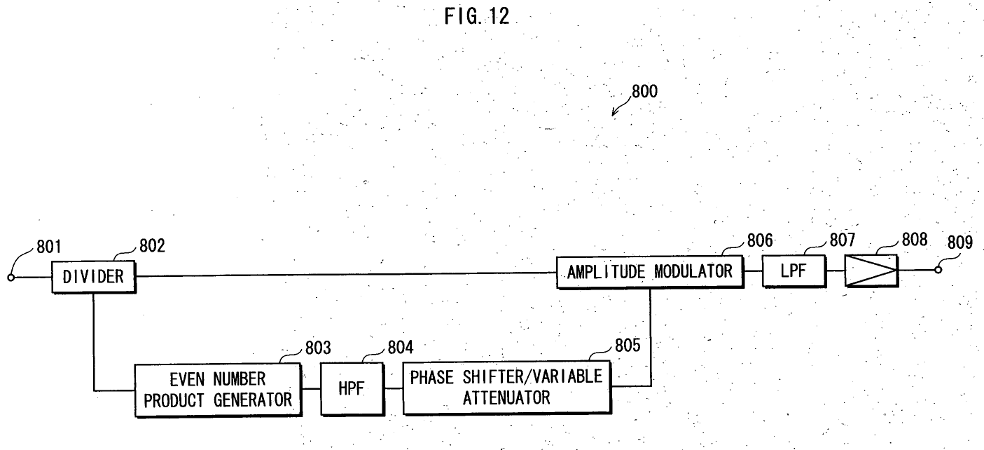

### BEST MODE FOR CARRYING OUT THE INVENTION

The following describes embodiments of the present invention with reference to the drawings.

### First Embodiment

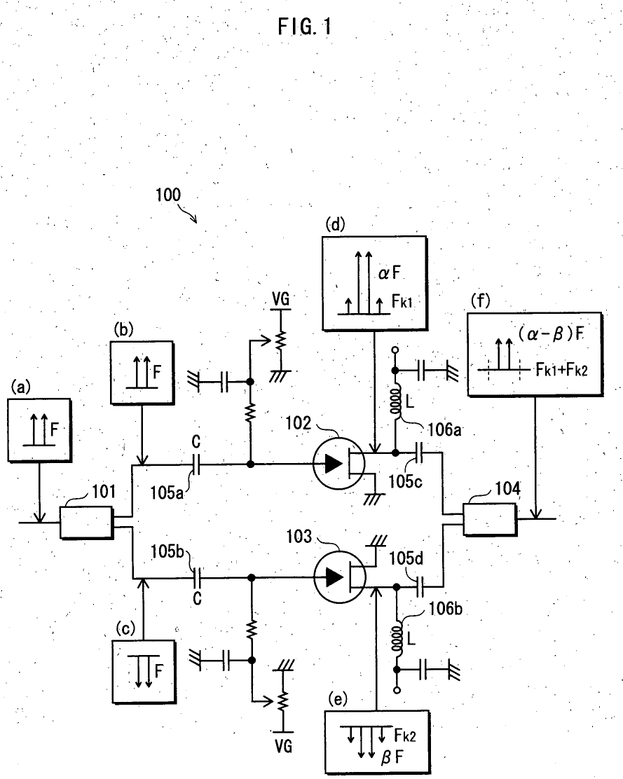

The following describes a first embodiment with reference to FIGS. 1 to 6.

### 1. OUTLINE

An amplifier circuit 100 of the first embodiment amplifies a multicarrier signal that has been obtained by multiplexing a plurality of carrier signal having different frequencies.

Here, for convenience, the description is given illustrating signal components F₁ and F₂ having respective frequencies f₁ and f₂ that are two frequencies among those in the multicarrier signal.

The amplifier circuit 100 divides an input signal into two paths. Class A amplification is performed on one of the paths, and class AB amplification is performed on the other of the paths to suppress the intermodulation distortion signal that accompanies the class A modulation.

### 2. STRUCTURE

The following describes the structure of the amplifier circuit 100 with reference to FIG. 1.

FIG. 1 is a block diagram showing the structure of the amplifier circuit 100.

The amplifier circuit 100 is composed of a divider 101, a first amplifier 102, a second amplifier 103, a combiner 104, capacitors (C) 105a to 105d, and inductors (L) 106a and 106b.

The divider 101, which is a 0-π balun, divides the input signal into the two paths. Specifically, the divider 101 outputs the input signal components F₁ and F₂ without rotating their phase to the path on which the first amplifier circuit 102 is provided, and outputs the input signal components F₁ and F₂ with their phase rotated 180 degrees to the path on which the second amplifier circuit 103 is provided.

The first amplifier 102, which is a GaN-HEMT (Gallium Nitride High Electron Mobility Transistor), is capable of amplifying input signal components F₁ and F₂ input via the capacitor 105a, to a level α times higher than the original level, and adjusting the level of amplification by adjusting the gate voltage.

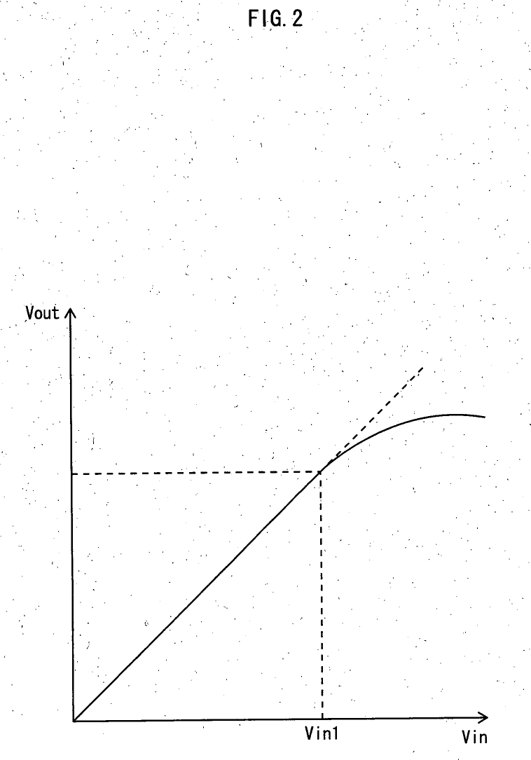

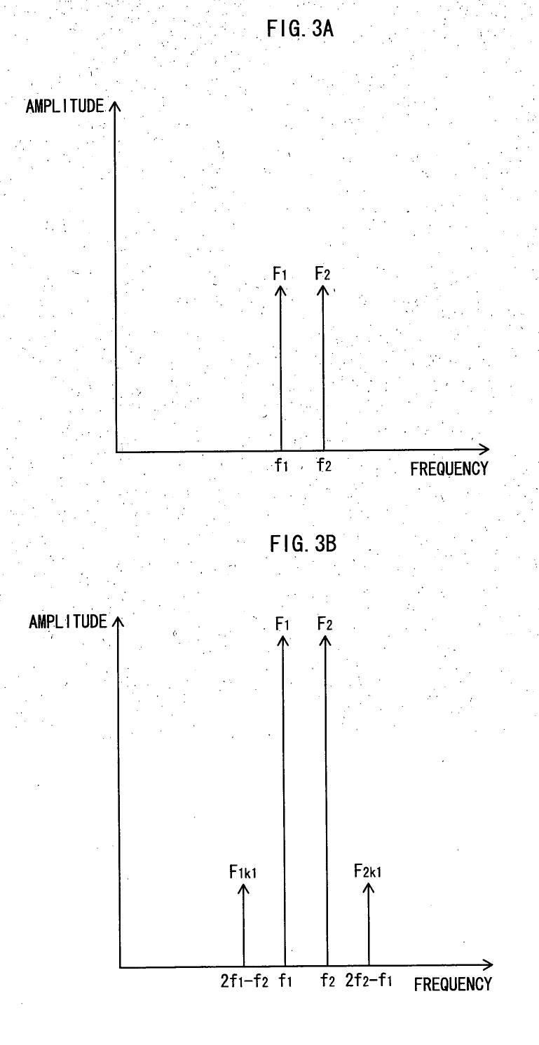

Here, the nonlinear characteristics of the first amplifier 102 are described with reference to FIGS. 2 and 3.

FIG. 2 is a graph showing input voltage Vin versus output voltage Vout characteristics of the first amplifier 102.

Referring to FIG. 2, in accordance with the nonlinear property of the first amplifier 102, an output voltage Vout proportionate to the input voltage Vin can be obtained up to a predetermined level Vin1, but when the input voltage Vin exceeds the level Vin1, the relationship falls below an ideal proportionate value (linear value).

As a result, if the signal is amplified to the nonlinear characteristic region in the first amplifier 102, an intermodulation distortion signal occurs in frequency bands in the vicinity of the signal.

FIG. 3 is a graph showing the frequency versus amplitude relationship, for explaining the intermodulation distortion signal that occurs in the frequency bands in the vicinity of multicarrier signal components F₁ and F₂.

As shown in FIG. 3, when the multicarrier signal components F₁ and F₂ are amplified to the nonlinear characteristic region that is Vin1 or greater in the first amplifier 102, (2F₁-F₂) and (2F₂-F₁) occur as main intermodulation distortion signal components of the multicarrier signal components F₁ and F₂.

Returning to the description of the structure of the amplifier circuit 100, the second amplifier 103 is a GaN-HEMT identical to the first amplifier 101. The second amplifier 103 amplifies input signal components F₁ and F₂ input via the capacitor 105a, and is capable of adjusting the level of amplification by adjusting the gate voltage.

Given that the second amplifier 103 also has nonlinear characteristics, if the multicarrier input signal components F₁ and F₂ are amplified to the nonlinear characteristic region, (2F₁-F₂) and (2F₂-F₁) occur as main intermodulation distortion signal components of the multicarrier signal components F₁ and F₂.

The combiner 104, which is a 0-0 balun, combines (a) the input signal components F₁ and F₂ and intermodulation distortion signal components (2F₁-F₂) and (2F₂-F₁) output from the first amplifier 102 via the inductor 106a with (b) the input signal components F₁ and F₂ and the reversed-phase intermodulation distortion signal components (2F₁-F₂) and (2F₂-F₁) output from the first amplifier 102. The combiner 104 outputs the resultant signal as an output signal.

### 3. WORKINGS

Referring once again to FIG. 1, the following describes workings of the amplifier circuit 100.

Given that the power of the input signal components F₁ and F₂ is substantially equal, hereinafter F is used to collectively denote the power of both signal components.

The input signal input into the amplifier circuit 100 includes the input signal components F₁ and F₂ having power F ((a) in FIG. 1).

When the input signal passes through the divider 101, an input signal having input signal components F₁ and F₂ of power F with normal phase passes along the path on which the first amplifier 102 is provided ((b) in FIG. 1).

Similarly, an input signal having input signal components F₁ and F₂ of power F with reversed phase passes along the path on which the second amplifier 103 is provided ((c) in FIG. 1).

On the path on which the first amplifier 102 is provided, the input signal is class-A amplified by the first amplifier 102 to a level α times the original level. As a result, input signal components F₁ and F₂ of power αF, and intermodulation distortion signal components (2F₁-F₂) and (2F₂-F₁) of power Fₖ₁ are generated ((d) in FIG. 1).

Meanwhile, on the path on which the second amplifier 103 is provided, the input signal is class-AB amplified by the second amplifier 103 to a level β times the original level (α>β). As a result, input signal components F₁ and F₂ of power βF, and intermodulation distortion signal components (2F₁-F₂) and (2F₂-F₁) of power Fₖ₂ are generated ((e) in FIG. 1).

Finally, the input signal components F₁ and F₂ of power αF and the intermodulation distortion signal components (2F₁-F₂) and (2F₂-F₁) of power Fₖ₁, which have normal phase, are combined by the combiner 104 with the input signal components F₁ and F₂ of power βF and the intermodulation distortion signal components (2F₁-F₂) and (2F₂-F₁) of power Fₖ₂, which have reversed phase.

Here, in the second amplifier 103, the level of amplification level is adjusted such that the power Fₖ₂ will be the same as the power Fₖ₁, and set to an optimum level of amplification β.

Specifically, the drain current is adjusted by changing the gate voltage VG. If the gate voltage VG is lowered, the drain current drops and greater intermodulation distortion is generated with a smaller input signal. This characteristic is utilized to adjust the gate voltage VG such that Fₖ₁ and Fₖ₂ are made to be as close to each other as possible while checking the wave form of the output signal output from the combiner 104.

As a result, when the signals are combined in the combiner 104, the intermodulation distortion signal components (2F₁-F₂) and (2F₂-F₁) of power Fₖ₁ and the distortion signal components (2F₁-F₂) and (2F₂-F₁) of power Fₖ₂, whose respective phases differ 180 degrees, cancel each other out, thus enabling the intermodulation distortion signal of power Fₖ₁ to be suppressed.

With the described structure, the intermodulation distortion signal generated due to the amplification in the first amplifier 102 can be easily suppressed by adjusting the level of amplification in the second amplifier 103.

### 4. MULTISTAGE STRUCTURE

A plurality of amplifier circuits 100 can be connected to form a multistage structure.

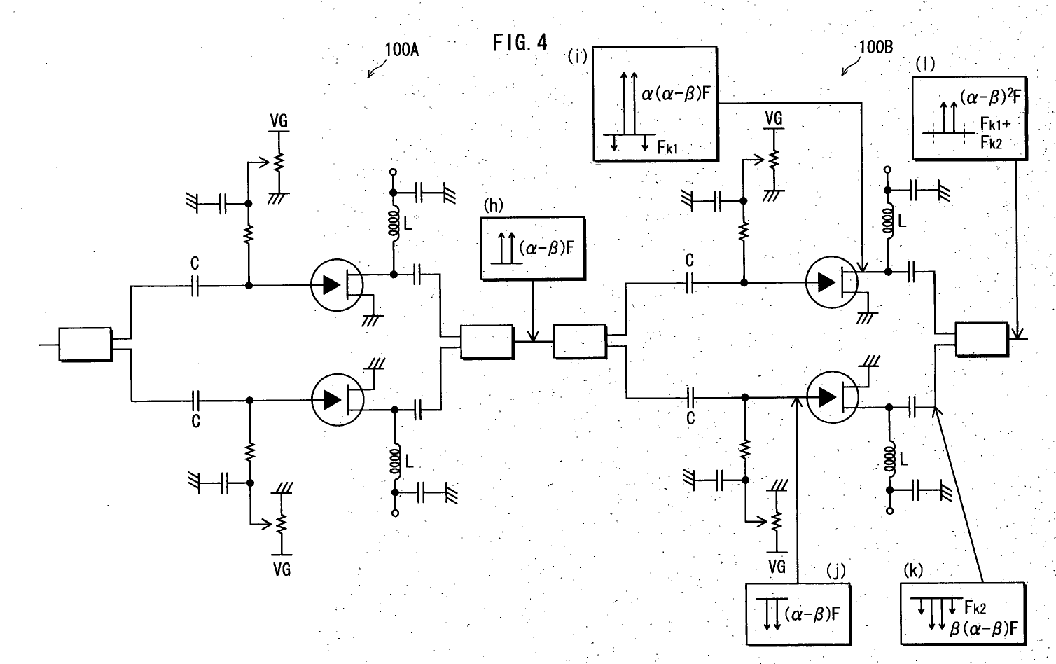

The following describes this multistage structure with reference to FIG. 4.

FIG. 4 is a block diagram showing a multistage structure in which two amplifier circuits 100 (100A and 100B) are serially connected.

In the amplifier circuit 100A, signal components F₁ and F₂ of power F are input, resulting in signal components F₁ and F₂ of power (α-β) being generated, as described earlier.

In the amplifier circuit 100B, the signal components F₁ and F₂ of power (α-β) are input, and ultimately input signal components F₁ and F₂ of power α(α-β) and input signal components F₁ and F₂ of power β(α-β), whose respective phases differ from each other by 180 degrees, are combined. This generates an input signal component of power (α-β)². Similarly, intermodulation distortion signal components (2F₁-F₂) and (2F₂-F₁) of power Fₖ₁ and intermodulation distortion signal components (2F₁-F₂) and (2F₂-F₁) of power Fₖ₂, whose respective phases differ from each other by 180 degrees, are combined. This results in the intermodulation distortion signal components canceling each other out ((1) in FIG. 4).

In this way, by serially connecting a plurality of amplifier circuits 100 in a multistage structure, the level of amplification in each individual amplifier circuit 100 can be kept low, and the output power can be gradually increased in stages. Increasing the output power in stages enables the amplification level in each first amplifier in the amplifier circuit can be kept relatively low, and the intermodulation distortion signals to be cancelled easily compared to a structure in which a signal is amplified greatly at once.

### 5. APPLICATION EXAMPLE

The following describes specific examples of an application of the amplifier circuit 100.

5-1. Digital Broadcast Repeater

Application example 1 is an example of the amplifier circuit 100 being applied to a digital broadcast repeater.

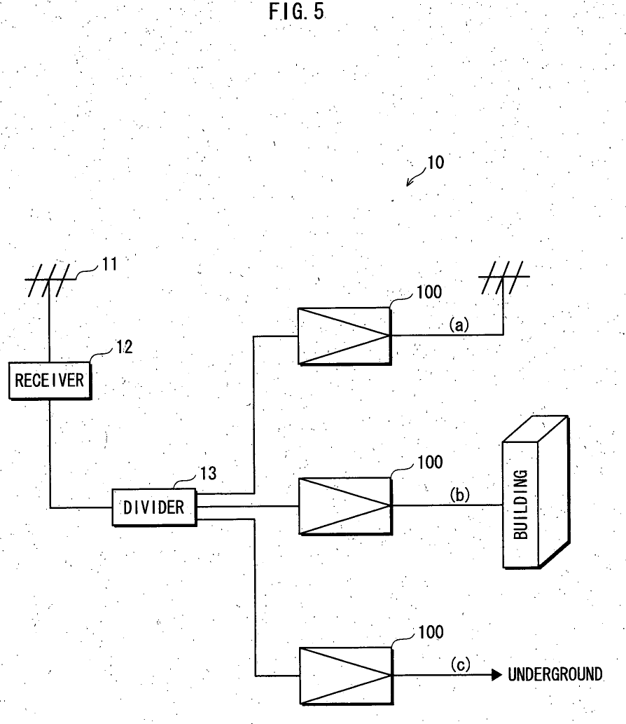

As shown in FIG. 5, a digital broadcast repeater 10 uses a receiver 12 to receive a digital broadcast wave via an antenna 11 from a digital broadcast station or a digital broadcast repeater, uses a divider 13 to then divide the broadcast wave to relay it elsewhere.

In the example in FIG. 5, the digital broadcast repeater 10 relays the divided digital broadcast wave to another digital broadcast repeater (path (a)), a building (path (b)), and underground (path (c)).

The amplifier circuits 100 are provided on each relay path so that the digital broadcast wave divided by the divider 13 can be relayed with greater power.

Note that the digital broadcast signal is, for instance, a signal that has been multiplexed according to an OFDM (orthogonal frequency division multiplex) method, and is composed of multiple subcarriers that lie next to each other in a set frequency band.

The following describes requirements for the amplifier circuit 100 used in a digital broadcast relayer.

In consideration of PEP (peak envelop power), it is necessary that the output from the power amplifier circuit in a digital broadcast repeater is a predetermined value of greater.

For instance, in Japan, “Chijo Digital Hosoyo Soshin Setsubi Kyotsu Shiyosho” (“Common Specifications for Digital Terrestrial Broadcast Transmission Equipment”, or “Orange Book”), published by the national Digital Transmission Equipment Study Group under the guidance of the Ministry of Internal Affairs and Communications, specifies that the output of a power amplifier circuit must be 80 W (approximately 50 dBm) or higher.

Furthermore, the strength of the nonlinear distortion signal that accompanies amplification in the power amplifier circuit must be no greater than a predetermined value in order to minimize effects on neighboring frequency bands. For instance, Japanese Radio Law specifies that the strength of the nonlinear distortion signal must be less than 50 μW (approximately −13 dBm).

In order to fulfill these specifications, a two-stage structure is used in which a low-power amplifier IC (integrated circuit) is provided in the former stage to amplify the input signal to an extent, and the amplifier circuit 100 is provided in the latter stage.

The following describes this structure in detail.

In the amplifier circuit 100 in the first stage, the capacitors 105a to 105d on the path are 100 pF (picofarad) capacitors. The first amplifier 102 and the second amplifier 103 are 10 W GaN-HEMTs (for instance, product number EGN010MK by Eudyna Devices Inc.) set so as to exhibit appropriate characteristics for a digital broadcast frequency band. The resistors for adjusting the gate voltage of the GaN-HEMTs are 100Ω gate series resistors. The inductors 106a and 106b are 10 μH (microhenry) choke coils.

In the amplifier circuit 100 in the second stage, the capacitors 105a to 105d on the path are 100 pF capacitors. The first amplifier 102 and the second amplifier 103 are 90 W GaN-HEMTs (for instance, product number EGN090MK by Eudyna Devices Inc.) set so as to exhibit appropriate characteristics for a digital broadcast frequency band. The resistors for adjusting the gate voltage of the GaN-HEMTs are 100Ω gate series resistors. The inductors 106a and 106b are 10 μH choke coils.

5-2. Mobile Communications Repeater

Application example 2 is an example of the amplifier circuit 100 being applied to a mobile communications repeater.

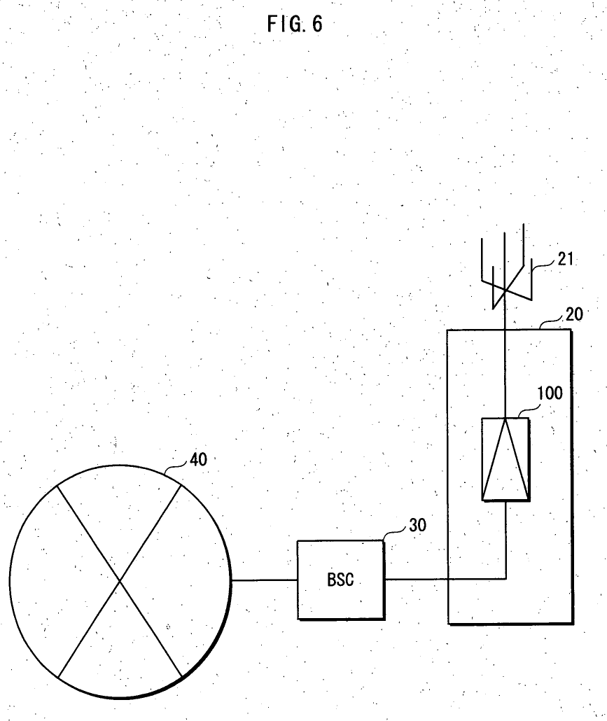

As shown in FIG. 6, a mobile communications base station 20 is connected via a BSC (base station controller) 30 to a public telephone network 40 which is a backbone. The mobile communications based station 20 transmits a signal received from the BSC 30, to a lower mobile communication terminal (not illustrated) via an antenna 21.

The amplifier circuits 100 are provided so that a signal received from the BSC 30 can be transmitted with greater power.

Japanese Radio Law also specifies that the strength of the nonlinear distortion signal that accompanies amplification in the amplifier circuit 100 used in the mobile communications base station must be less than 500 μW (approximately −13 dB).

In the application example 2, the amplifier circuits 100 are used in a three-stage structure.

The following describes this structure in detail.

In the amplifier circuit 100 in the first stage, the capacitors 105a to 105d on the path are 22 pF capacitors. The first amplifier 102 and the second amplifier 103 are 30 W GaN-HEMTs (for instance, product number EGN030MK by Eudyna Devices Inc.) set so as to exhibit appropriate characteristics for a mobile communications frequency band. The resistors for adjusting the gate voltage of the GaN-HEMTs are 33Ω gate series resistors. The inductors 106a and 106b are λ/4 wires.

In the amplifier circuit 100 in the second stage, the capacitors 105a to 105d on the path are 22 pF capacitors. The first amplifier 102 and the second amplifier 103 are 90 W GaN-HEMTs (for instance, product number EGN090MK by Eudyna Devices Inc.) set so as to exhibit appropriate characteristics for a mobile communications frequency band. The resistors for adjusting the gate voltage of the GaN-HEMTs are 33Ω gate series resistors. The inductors 106a and 106b are λ/4 wires.

In the amplifier circuit 100 in the third stage, the capacitors 105a to 105d on the path are 22 pF capacitors. The first amplifier 102 and the second amplifier 103 are 180 W GaN-HEMTs (for instance, product number EGN21A1801V by Eudyna Devices Inc.) set so as to exhibit appropriate characteristics for a mobile communications frequency band. The resistors for adjusting the gate voltage of the GaN-HEMTs are 33Ω gate series resistors. The inductors 106a and 106b are λ/4 wires.

### Second Embodiment

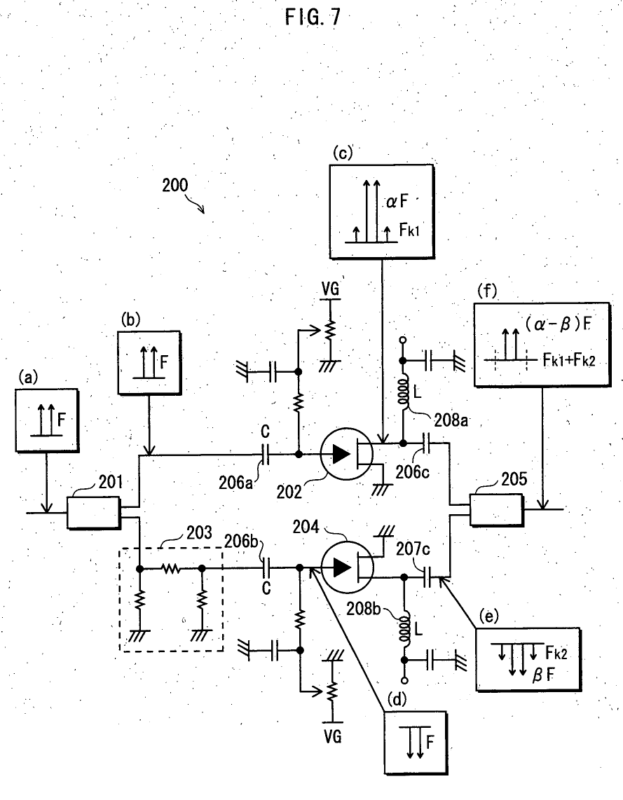

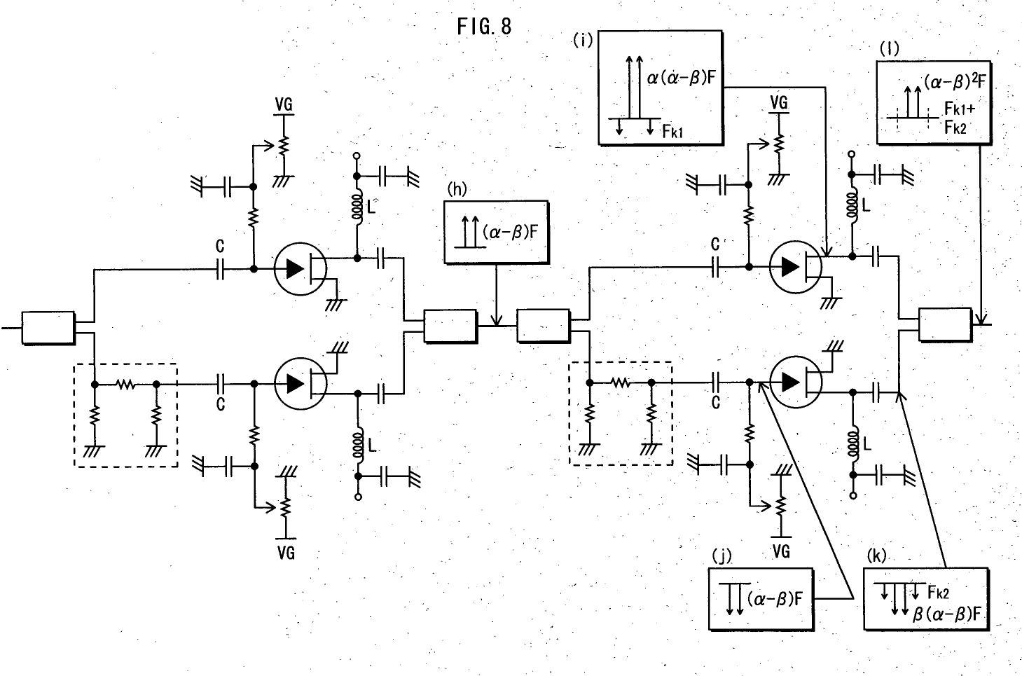

The following describes a second embodiment with reference to FIGS. 7 and 8.

### 1. OUTLINE

Whereas the first embodiment used a structure in which two identical amplifiers (the first amplifier and the second amplifier) are connected in parallel and the level of amplification of the second amplifier is reduced using the gate voltage, an amplifier circuit 200 in the second embodiment has a structure that uses a second amplifier that has a lower level of amplification than a first amplifier.

Here, for convenience, the description is given illustrating signal components F₁ and F₂ of frequencies f₁ and f₂ that are two frequencies among those in a multicarrier signal.

### 2. STRUCTURE

The following describes the structure of the amplifier circuit 200 with reference to FIG. 7.

As shown in FIG. 7, the amplifier circuit 200 is composed of a divider 201, a first amplifier 202, a resistor circuit 203, a second amplifier 204, a combiner 205, capacitors (C) 206a to 206d, and inductors (L) 207a and 207b.

The divider 201 is a 0-π balun with an identical structure to the divider 101 of the first embodiment.

The first amplifier 202 is a GaN-HEMT with an identical structure to the first, amplifier 102 of the first embodiment, and is capable of amplifying input signal components F₁ and F₂ to a level times higher than the original level.

The second amplifier 204 is a GaN-HEMT having a lower level of amplification that the first amplifier 202, and is capable of amplifying input signal components F₁ and F₂.

The resistor circuit 203 is a plurality of resistors for dividing and adjusting voltage to be input into the second amplifier 204 since the rated voltage of the first amplifier 202 and the rated voltage of the second amplifier 204 being different.

The combiner 205 has an identical structure to the combiner 104 of the first embodiment.

### 3. WORKINGS

The effects of the present embodiment are, as shown in FIG. 7, the same as the amplifier 100 of the first embodiment, and the level of amplification of the second amplifier 204 can be adjusted to an optimum level of amplification β by adjusting the gate voltage.

With this structure, the same effects as the amplifier circuit 100 of the first embodiment can be obtained using a device with a low level of amplification and low rated voltage for the second amplifier 204. This realizes reduced manufacturing costs.

### 4. MULTISTAGE STRUCTURE

As shown in FIG. 8, the amplifier circuit 200 can be used for a multistage structure in the same way as the amplifier circuit 100 of the first embodiment.

### Third Embodiment

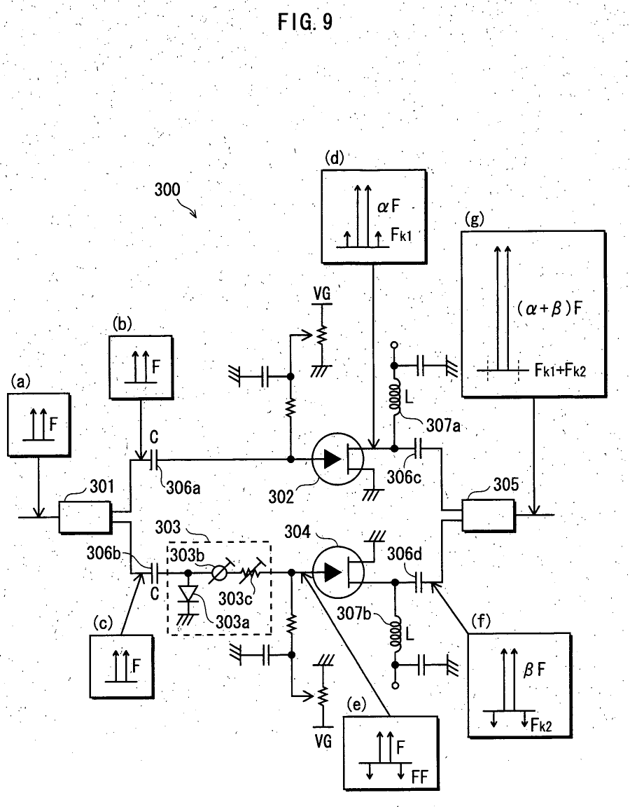

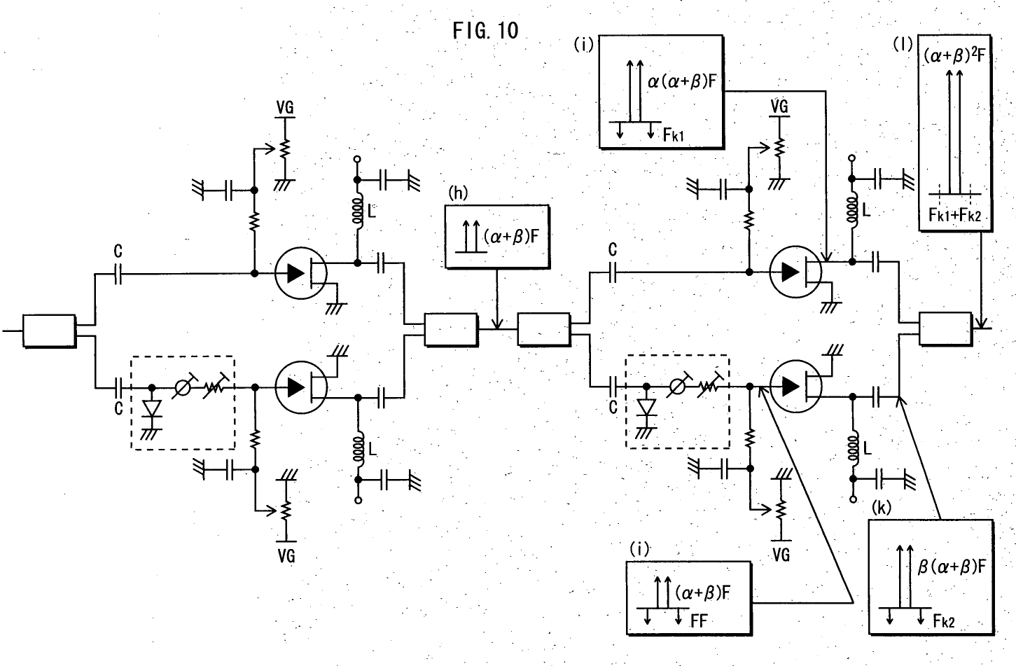

The following describes a third embodiment with reference to FIGS. 9 and 10.

### 1. OUTLINE

The first and second embodiments are structured such that the input signal is divided into two paths by a divider, and the phase of the signal output to one of the paths is rotated 180 degrees. The third embodiment is structured such that a signal of normal phase is output to both paths by the divider, and a distortion circuit is provided on one of the paths to generate a distortion signal.

Here, for convenience, the description is given illustrating signal components F₁ and F₂ of frequencies f₁ and f₂ that are two frequencies among those in a multicarrier signal.

### 2. STRUCTURE

The following describes the structure of the amplifier circuit 300 with reference to FIG. 9.

As shown in FIG. 9, the amplifier circuit 300 is composed of a divider 301, a first amplifier 302, a distortion circuit 303, a second amplifier circuit 304, and a combiner 305.

The divider 301, which is a 0-0 balun, outputs input signal components F₁ and F₂ that have normal phase to the path on which the first amplifier circuit 302 is provided and the path on which the second amplifier circuit 304 is provided, repectively.

The first amplifier 302 is a GaN-HEMT having the structure described in the first and second embodiments, and is capable of amplifying input signal components F₁ and F₂ to a level a times higher than the original level.

The distortion circuit 303 is a circuit that includes a diode 303a, a variable phase shifter 303b, and a variable attenuator 303c, and generates distortion signal components with reversed phase in the vicinity of the frequency of the input signal components F₁ and F₂ input with normal phase.

Specifically, the diode 303a, which is biased in the nonlinear operational region, compresses the waveform of the input signal components F₁ and F₂, and outputs distortion signal components (2F₁-F₂) and (2F₂-F₁) that include the higher harmonics of the input signal components F₁ and F₂.

The variable phase shifter 303b gives a lag amount to the phase of the distortion signal components (2F₁-F₂) and (2F₂-F₁) to rotate the phase 180 degrees, resulting in reversed phase.

The variable attenuator 303c adjusts the attenuation ratio of the distortion signal components (2F₁-F₂) and (2F₂-F₁).

Distortion signal components (2F₁-F₂) and (2F₂-F₁) having reversed phase are generated in the input signal components F₁ and F₂ that pass through the distortion circuit 303 having the described structure.

The second amplifier 304 is a GaN-HEMT identical to the first amplifier 302, and capable of amplifying the distortion signal components (2F₁-F₂) and (2F₂-F₁) generated by the input signal components F₁ and F₂ passing through the distortion circuit 303.

The combiner 305 has the same structure as the combiners of the first and second embodiments.

### 3. WORKINGS

Referring once again to FIG. 9, the following describes effects of the amplifier circuit 300.

Given that the power of the input signal components F₁ and F₂ is substantially equal, hereinafter F is used to collectively denote the power of both signal components.

The input signal input into the amplifier circuit 300 has the input signal components F₁ and F₂ having power F ((a) in FIG. 9).

When the input signal passes through the divider 301, an input signal having input signal components F₁ and F₂ of power F with normal phase passes along the path on which the first amplifier 302 is provided ((b) in FIG. 9).

Similarly, an input signal having input signal components F₁ and F₂ of power F with reversed phase passes along the path on which the second amplifier 304 is provided ((c) in FIG. 9).

On the path on which the first amplifier 302 is provided, the input signal is amplified by the first amplifier 302 to be α times the original level. As a result, input signal components F₁ and F₂ of power αF, and intermodulation distortion signal components (2F₁-F₂) and (2F₂-F₁) of power Fₖ₁ are generated ((d) in FIG. 9).

Meanwhile, on the path on which the second amplifier 304 is provided, due to the input signal having passed through the distortion circuit 303, input signal components F₁ and F₂ of power F and intermodulation distortion signal components (2F₁-F₂) and (2F₂-F₁) of power FF and with reverse phase to the input signal components F₁ and F₂ of power F pass through ((e) in FIG. 1).

The input signal components F₁ and F₂ of power F and the intermodulation distortion signal components (2F₁-F₂) and (2F₂-F₁) of power FF are then amplified to a level β times higher by passing through the second amplifier 304, and, as a result, input signal components F₁ and F₂ of power Fₖ₂ and intermodulation distortion signal components (2F₁-F₂) and (2F₂-F₁) of power Fₖ₂ are generated ((f) in FIG. 1).

Finally, the input signal components F₁ and F₂ of power αF and the intermodulation distortion signal components (2F₁-F₂) and (2F₂-F₁) of power Fₖ₁ are combined by the combiner 305 with the input signal components F₁ and F₂ of power βF and the intermodulation distortion signal components (2F₁-F₂) and (2F₂-F₁) of power Fₖ₂.

As a result, the input signal components F₁ and F₂ of power αF and the input signal components F₁ and F₂ of power βF, which have the same phase, are combined, resulting in an input signal components of power (α+β) F being generated. Furthermore, the intermodulation distortion signal components (2F₁-F₂) and (2F₂-F₁) of power Fₖ₁ and the intermodulation distortion signal components (2F₁-F₂) and (2F₂-F₁) of power Fₖ₂, whose respective phases differ 180 degrees, are combined ((f) in FIG. 1).

Here, in the second amplifier 304, the level of amplification is adjusted such that the power Fₖ₂ will be the same as the power Fₖₗ, and set to an optimum level of amplification β.

Specifically, the drain current is adjusted by changing the gate voltage VG. If the gate voltage VG is lowered, the drain current drops and greater intermodulation distortion is generated with a smaller input signal. This characteristic is utilized to adjust the gate voltage VG such that Fₖ₁ and Fₖ₂ are made to be as close to each other as possible.

With the described structure, the intermodulation distortion signal generated due to the amplification in the first amplifier 302 can be easily suppressed by adjusting the level of amplification in the second amplifier 304.

### 4. MULTISTAGE STRUCTURE

As shown in FIG. 10, the amplifier circuit 300 can also be used for a multistage structure in the same way as the amplifier circuit 100 of the first embodiment.

### 5. APPLICATION EXAMPLE

The amplifier circuit is subject to age, with a difference arising in the level of amplification of the first amplifier and the second amplifier due to environmental changes such as temperature with the passage of time.

In order to deal with deterioration in suppression of the intermodulation distortion signal to due aging, a compensation circuit is further provided in the amplifier circuit 300 that includes a distortion circuit.

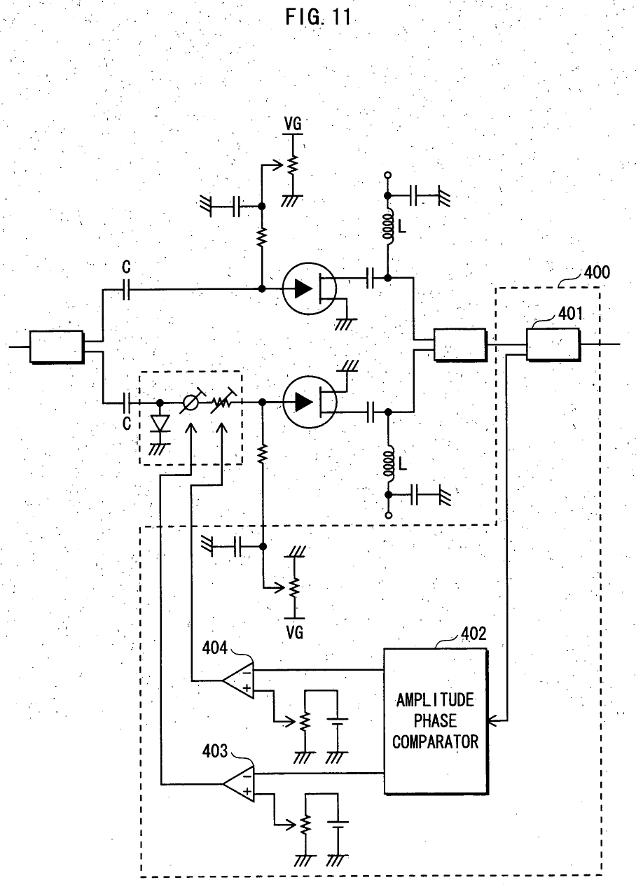

The following describes the structure of a compensation circuit 400 with reference to FIG. 11.

As shown in FIG. 11, the compensation circuit 400 is connected to the output terminal of the amplifier circuit 300 of the third embodiment, and is composed of a divider 401, an amplitude phase comparator 402, an opamp 403, and an opamp 404.

The divider 401, which is a 0-0 balun for instance, receives input of an output signal (called “Out” here) output from the amplifier circuit 300, divides the output signal Out into two paths, one being an output path and the other being the amplitude phase comparator 402.

The amplitude phase comparator 402 has an internal recording medium in which it stores phase and power threshold values of the intermodulation distortion signal included in the output signal Out. The amplitude phase comparator 402 successively measures the output signal Out input via the divider 402, and compares the phase, and power of the intermodulation distortion signal with the respective threshold values. When the result of the comparison shows that the phase of the output signal Out deviates from the threshold value, the amplitude phase comparator 402 instructs the opamp 403 to correct this deviation. When the result of the comparison shows that the power of the output signal Out deviates from the threshold value, the amplitude phase comparator 402 instructs the opamp 404 to correct this deviation.

The opamp 403 issues a control voltage to the variable phase shifter 303b of the distortion circuit 303 to delay or advance the phase based on an instruction from the amplitude phase comparator 402.

The opamp 404 issues a control voltage to change the amount of attenuation by the variable attenuator 303c of the distortion circuit 303 based on an instruction from the amplitude phase shifter 402.

With this kind of structure, if the accuracy of the distortion signal generated by the distortion circuit 303 of the amplifier circuit 300 deteriorates due to aging, the variable phase shifter 303b can be adjusted to deal with deviation in the phase, and the variable attenuator 303c can be adjusted to deal with deviation in the power. The realizes an amplifier circuit that is resistant to aging.

### Supplementary Remarks

Although the amplifier circuit of the present invention has been described based on the above first to third embodiments, various modification to the structure of the amplifier circuit are possible.

(1) In the first and second embodiments, the dividers 101 and 201 are not limited to being a 0-π balun. Any kind of device that divides a signal into two paths, and outputs the signals with the phase of one of the signals rotated by 180 degrees may be used, an example of which being a 180 degree hybrid.

(2) In the first to third embodiments, the combiners 104, 205 and 305 are not limited to being a 0-0 balun. Any kind of device that combines signals of two paths and outputs the resultant combined signal may be used, an example of which being a directional coupler.

(3) In the first to third embodiments, the first amplifier and the second amplifier are not limited to being a GaN-HEMT.

Examples of alternatives are: a vacuum tube, a traveling wave tube, a klystron tube, and a semiconductor device such as a N-type transistor, a P-type transistor, a silicon semiconductor, an MOS-FET (Metal Oxide Semiconductor Field Effect Transistor), an LD-MOS (Laterally Diffused Metal Oxide Semiconductor), and a GaAs semiconductor.

(4) In the first to third embodiments, the distortion signal is not limited to being generated using an input signal divided by the divider. Given that it is sufficient for the circuit structure to be one that amplifies the distortion signal in a second amplifier provided separately to the first amplifier, the structure may be such that a signal having the same plural frequencies as the input signal is input independently into the second amplifier.

(5) Although a digital broadcast repeater and a mobile communications base station are given as examples of applications of the amplifier circuit in the first embodiment, the amplifier circuit is not limited to being applied to these, and has various applications in signal amplification. Examples of the wide range of frequency bands that the present invention may be applied to are audio frequency, ultrasonic waves, low frequency waves, high frequency waves, microwaves, millimeter waves, electron beams, X-rays, visible light and ultraviolet rays.

### INDUSTRIAL APPLICABILITY

The amplifier circuit of the present invention has wide-ranging applicability in transmission devices in which amplification of signals is necessary, such as digital broadcast transmission equipment and mobile communications base stations. The present invention provides an effective, low-cost technology for easily reducing effects of intermodulation distortion signals.

1. An amplifier circuit comprising:
a first amplifier and a second amplifier for amplifying an input signal that includes a plurality of frequency components;
a combiner for combining an output signal of the first amplifier with an output signal of the second amplifier; and
a divider for dividing the input signal into the first amplifier and the second amplifier,
wherein
a circuit structure of the amplifier circuit is such that distortion compensation is performed as a result of the combining, by using a signal in the output signal of the second amplifier to suppress a signal of a frequency component caused by intermodulation distortion in the output signal of the first amplifier, the signal in the output signal of the second amplifier having a reverse characteristic to the frequency component,
the input signal includes a signal component of frequency f₁ and a signal component of frequency f₂,
the divider divides the input signal to the first amplifier without changing a phase of the input signal, and divides the input signal to the second amplifier with the phase reversed,
the first amplifier and the second amplifier are connected in parallel between the divider and the combiner,
the divider and the second amplifier are connected via a resistor circuit that includes a resistor for dividing voltage of an output signal of the divider, and supplying a resultant signal to the second amplifier circuit,
the combiner combines the output signal of the first amplifier with the output signal of the second amplifier without changing a phase of each output signal, and
the first amplifier and the second amplifier are set such that at least (a) a signal component of frequency (2f₁-f₂) caused by intermodulation distortion in the output signal of the first amplifier and (b) a signal component of frequency (2f₁-f₂) in the output signal of the second amplifier cancel each other out as the result of the combining.

2-7. (canceled)

8. The amplifier circuit of claim 1, wherein
the second amplifier has a lower rated voltage than the first amplifier.

9. The amplifier circuit of claim 1, wherein
each of the first amplifier and the second amplifier is a GaN-HEMT, and composed of an internal matching integrated circuit.

10. The amplifier circuit of claim 1, wherein
each of the first amplifier and the second amplifier is an LD-MOS.

11. An amplifier circuit comprising:
a first amplifier and a second amplifier for amplifying an input signal that includes a plurality of frequency components;
a combiner for combining an output signal of the first amplifier with an output signal of the second amplifier; and
a divider for dividing the input signal into the first amplifier and the second amplifier, wherein
a circuit structure of the amplifier circuit is such that distortion compensation is performed as a result of the combining, by using a signal in the output signal of the second amplifier to suppress a signal of a frequency component caused by intermodulation distortion in the output signal of the first amplifier, the signal in the output signal of the second amplifier having a reverse characteristic to the frequency component,
the input signal includes a signal component of frequency f₁ and a signal component of frequency f₂,
the first amplifier and the second amplifier are connected in parallel between the divider and the combiner,
the divider and the second amplifier are connected via a distortion circuit that causes intermodulation distortion in an output signal of the divider,
the distortion circuit includes a variable phase shifter, a variable attenuator, and a diode that adjusts a phase relationship between frequency components of the output signal of the divider, and
the distortion circuit, the divider and the combiner are structured such that at least (a) a signal component of frequency (2f₁-f₂) caused by intermodulation distortion in the output signal of the first amplifier and (b) a signal component of frequency (2f₁-f₂) in the output signal of the second amplifier cancel each other out as a result of the combining.

12. The amplifier circuit of claim 10, further comprising:
a setting circuit for successively measuring an output signal that is a result of amplification by the amplifier circuit, and, in accordance with a result of measuring, setting an amount of variation in the variable phase shifter and an amount of variation in the variable attenuator.

13. The amplifier circuit of claim 10, wherein
the second amplifier has a lower rated voltage than the first amplifier.

14. The amplifier circuit of claim 10, wherein
each of the first amplifier and the second amplifier is a GaN-HEMT, and composed of an internal matching integrated circuit.

15. The amplifier circuit of claim 10, wherein
each of the first amplifier and the second amplifier is an LD-MOS.
